(19) United States
(12) Patent Application Publication
(10) Pub. No.: US 2007/0013471 A1
(43) Pub. Date: Jan. 18, 2007

(54) Superconducting coil, method for manufacturing thereof and welding device

(75) Inventors: Koichi Minami, Kanagawa (JP); Satoru Asai, Kanagawa (JP); Yoshinobu Makino, Tokyo (JP); Katsunori Shiihara, Kanagawa (JP); Toshio Kanahara, Kanagawa (JP)

Correspondence Address: FOLEY AND LARDNER LLP;SUITE 500, 3000 K STREET NW, WASHINGTON, DC, 20007, US

(73) Assignee: KABUSHIKI KAISHA TOSHIBA

(21) Appl. No.: 11/478,343

(22) Filed: Jun. 30, 2006

(30) Foreign Application Priority Data
Jul. 5, 2005 (JP) 2005-196480

(51) Int. Cl. H01F 27/28; H01L 39/24

(52) U.S. Cl. 336/225; 336/DIG. 1; 29/599

(57) ABSTRACT

In the method of manufacturing a superconducting coil, a superconducting line coated with an insulating member is contained in a groove formed on a surface of a stainless steel plate, and a stainless steel lid is fitted in outer side of the superconducting line in an opening in the groove. The lid is formed to fit in the groove. Then, the plate and the lid are welded to seal at joint sections. The welding is conducted using a plurality of heat sources including a laser and an arc so that melting depth at the joint section is within a predetermined range. The lid may have two joint sections, and the welding of the joint sections of the lid may be conducted simultaneously. The plate may have a plurality of grooves, and the welding of the joint sections of the lid may be conducted simultaneously.

### CROSS REFERENCE TO RELATED APPLICATION

The present invention contains subject matter related to Japanese Patent Application No. 2005-196480, filed in the Japanese Patent Office on Jul. 5, 2005, the entire content of which is incorporated herein by reference.

### BACKGROUND OF THE INVENTION

This invention relates to a method of manufacturing a superconducting coil for forming a forced-flow cooled superconducting magnet that can be used in a nuclear fusion facility or a particle accelerator, for example. More particularly, the present invention relates to a method of manufacturing a superconducting coil that is improved in the welding/assembling step thereof. This invention further relates to a superconducting coil and a welding device.

Superconducting coils have been and being developed in recent years. Forced flow cooled superconducting coils are a type of superconducting coils. Forced flow cooled superconducting coils can be directly insulated, so that it provides advantages including a highly remarkable mechanical strength in terms of structure and excellent electric insulation characteristics in terms of performance. Therefore, it is preferable to use the forced flow cooled superconducting coils in the field of large superconducting coils.

Applications of large superconducting coils include superconducting magnets to be used in nuclear fusion facilities and particle accelerators.

Large superconducting coils used in nuclear fusion facilities and particle accelerators are typically produced by cutting grooves on the opposite surfaces of stainless steel band plates for tightly holding superconducting lines, containing insulated superconducting lines in the grooves and sealing the openings of the grooves by means of stainless steel lids.

Thus, a superconducting coil is formed by stainless steel band plates, superconducting lines contained in the grooves of the band plates and lids closing the openings of the grooves.

Generally, a welding-sealing method is employed to close the grooves of the stainless steel band plates with the lids of the superconducting coil for sealing. Arc welding or laser welding is typically used for the welding-sealing method.

Composite welding methods of arranging edge preparation means for the butting surfaces of two members to be welded in front of two welding means are known (See, for example, Japanese Patent Application Laid-Open Publication No. 2004-298896, the entire content of which being incorporated herein by reference). The edge preparation means is arranged in the sense of the welding proceeding direction, and the two means are moved relative to the members to be welded along the butting surfaces. The two welding means include a laser head and an arc welding torch. The distance separating the two means is maintained so as to simultaneously carry out the composite welding operation of edge preparation of the butting surfaces by the edge preparation means and composite welding using a laser and an arc of the welding means.

Other composite welding methods of arranging a laser welding nozzle, a plasma torch and an assist gas projection nozzle on a welding route of the members to be welded are also known (See, for example, Japanese Patent Application Laid-Open Publication No. 10-216972, the entire content of which being incorporated herein by reference). In this method, the laser is the leader, and the arc is the follower. A proper value is selected for the distance separating the laser beam irradiation spot and the welding wire shooting position of the arc. At the same time, the inter-joint gap on the welding route of the members to be welded is defined so as to be not less than 10% of the band plate thickness and not more than the laser beam.

Still other composite welding methods of welding at least one to-be-welded joint section by means of a laser beam are known (See, for example, PCT International Publication WO 02/16071 A1 or Published Japanese Translation of PCT. International Publication for Patent Application No. 2004-525766, the entire content of which being incorporated herein by reference). The laser beam is typically emitted from a power diode laser equipment, and at least one electric arc supplement the output power of the laser welding arrangement.

The materials that are used for insulators of superconducting lines and superconducting coils of large superconducting coils are generally delicate to heat. Therefore, a welding operation has to be carried out, while controlling the heat input to the band plate and to the superconducting line by way the band plate. In this case, arc welding is used to close the opening of the groove containing the superconducting line for sealing by means of the lid.

The section to be welded of the lid is accompanied by a problem of thermal deformation, because neighboring welding lines are located close to each other so that it is necessary to precisely control the heat input.

Additionally, the superconducting coil is a large structure and the gaps of to-be-welded joint sections can fluctuate significantly so that it is important to control the heat input.

On the other hand, a large superconducting coil requires a high degree of assembling precision because of the performance required to it. Thus, any possible thermal deformation that can arise in the conventional arc welding step may cause problems. Therefore, it is necessary to prepare a superconducting coil according to a multiple welding sequence that is precisely controlled to suppress thermal deformations.

A method of manufacturing a large superconducting coil including an arc welding step involves a multiple welding sequence and thermal deformations can inevitably occur due to an excessive heat input.

Additionally, long working hours are required to manufacture a large superconducting coil and incidental works of removing strains are generally necessary to consequently reduce the productivity.

On the other hand, a laser welding method can reduce the welding heat input and possible thermal deformations so that a relatively high productivity can be expected if compared with arc welding. However, the laser welding method requires a high degree of assembling precision for to-be-welded joint sections, so that it is accompanied by a difficulty of cutting grooves in a band plate for containing superconducting lines and performing assembling operations.

With the known composite welding methods as described in Japanese Patent Application Laid-Open Publication Nos. 2004-298896 and 10-216972, while it is possible to increase the depth of melt when welding a thick plate, it is difficult to precisely control the welding heat input to the members to be welded. Therefore, the insulators of superconducting lines and the material of superconducting coils can be overheated and thermally damaged.

Additionally, when the gaps separating the to-be-welded joint sections of a large structure fluctuate, it is difficult to regulate them. Thus, it is difficult to produce good welded joint sections.

Furthermore, a very high degree of assembling precision is required for large superconducting coils, because high performances are required. On the other hand, thermal deformations of the welded members may occur due to the difficulty of heat input control with the composite welding methods described in Japanese Patent Application Laid-Open Publication Nos. 2004-298896 and 10-216972. Therefore, there is a problem that the required high degree of assembling precision for welding/assembling operations involving a multiple welding sequence cannot be achieved.

The known composite welding method as described in PCT International Publication WO 02/16071 A1 provides an advantage of supplementing the insufficient output power of laser welding by using both laser welding and arc welding. However, the insulators of superconducting lines and the material of superconducting coils can be overheated and thermally damaged to make it impossible to achieve a high degree of assembling precision. That is because precise control of the heat input is difficult as in the composite welding methods of Japanese Patent Application Laid-Open Publication Nos. 2004-298896 and 10-216972.

As described above, the conventional methods of manufacturing superconducting coils have problems of welding deformation and productivity in the case of arc welding, and a problem of restriction in assembling precision in the case of laser welding, particularly when having a welding/assembling step.

### SUMMARY OF THE INVENTION

In view of the above identified problems, it is therefore an object of the present invention to provide a method of manufacturing a superconducting coil that can suppress thermal deformations due to welding and to achieve a high degree of assembling precision and a high productivity without thermally damaging the superconducting lines.

In order to attain the object, according to an aspect of the present invention, there is provided a method of manufacturing a superconducting coil, the method comprising: containing a superconducting line coated with an insulating member in a groove formed on a surface of a stainless steel plate; fitting a stainless steel lid in outer side of the superconducting line in an opening in the groove, the lid being formed to fit in the groove; and welding the plate and the lid to seal at joint sections, wherein the welding is conducted using a plurality of heat sources including a laser and an arc so that melting depth at the joint section is within a predetermined range.

According to another aspect of the present invention, there is also provided a superconducting coil comprising: a stainless steel plate having at least one surface with at least one groove; a superconducting coil coated with an insulator contained in the groove; and a stainless steel lid fitted into the groove at outer side of the superconducting line; wherein: the lid has two joint sections on its sides where the lid is welded with the plate; and the joint sections have been welded using a plurality of heat sources including a laser and an arc so that melting depth at the joint section is within a predetermined range.

According to yet another aspect of the present invention, there is also provided a welding device for manufacturing a superconducting coil, the device adapted to be used for welding a stainless steel plate and a stainless steel lid to seal joint sections between the plate and the lid, the plate having at least one surface with at least one groove containing a superconducting coil coated with an insulator, the lid being fitted into the groove at outer side of the superconducting line, the device comprising: an automotive cart adapted to move along the joint sections; a laser welding mechanism for welding the joint sections, the laser welding mechanism mounted on the cart; and an arc welding mechanism for welding the joint sections, the arc welding mechanism mounted on the cart.

### BRIEF DESCRIPTION OF THE DRAWINGS

The above and other features and advantages of the present invention will become apparent from the discussion hereinbelow of specific, illustrative embodiments thereof presented in conjunction with the accompanying drawings, in which:

FIG. 1A is a schematic partial front view of a superconducting coil, illustrating the first embodiment of a method of manufacturing a superconducting coil according to the present invention;

FIG. 1B is a schematic partial lateral cross-sectional view of a superconducting coil, also illustrating the first embodiment of the method of manufacturing a superconducting coil according to the present invention;

FIG. 2 is a graph illustrating the effect of the shield gas mixing ratio according to the first embodiment of the present invention;

FIG. 3 is a graph illustrating the relationship between the melting depth and the highest ultimate temperature according to the first embodiment of the present invention;

FIG. 4 is a graph illustrating the relationship between the inter-joint gap and the highest ultimate temperature according to the first embodiment of the present invention;

FIG. 5 is a schematic lateral cross-sectional view of a superconducting coil, illustrating the second embodiment of the method of manufacturing a superconducting coil according to the present invention;

FIG. 6 is a schematic lateral cross-sectional view of a superconducting coil, illustrating the third embodiment of the method of manufacturing a superconducting coil according to the present invention;

FIG. 7A is a schematic partial front view of a superconducting coil, illustrating the fourth embodiment of the method of manufacturing a superconducting coil according to the present invention; and

FIG. 7B is a schematic partial lateral cross-sectional view of a superconducting coil, also illustrating the fourth embodiment of the method of manufacturing a superconducting coil according to the present invention.

### DETAILED DESCRIPTION OF THE INVENTION

Now, the present invention will be described in greater detail by referring to the accompanying drawings that illustrate preferred embodiments of the present invention.

[First Embodiment]

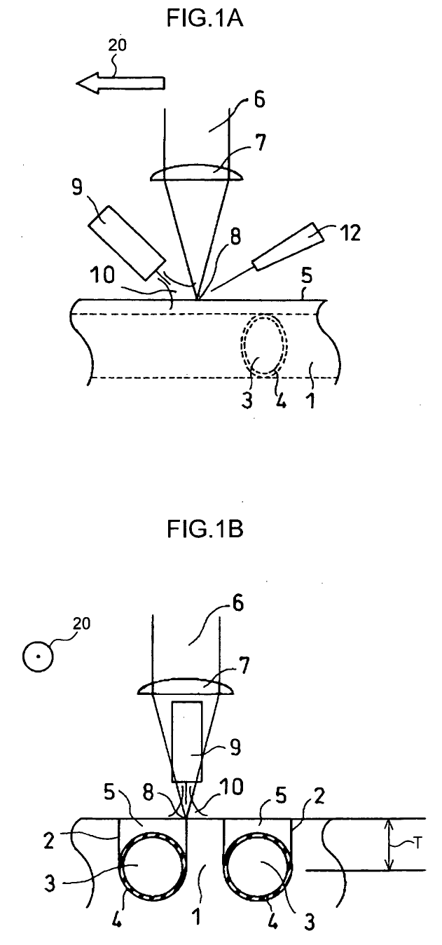

FIGS. 1A and 1B schematically illustrate the first embodiment of the present invention. FIG. 1A is a partial front view of a band plate of superconducting coil, illustrating the first embodiment, and FIG. 1B is a partial lateral cross-sectional view of the superconducting coil.

Referring to FIGS. 1A and 1B, reference symbol 1 denotes a band plate of austenitic stainless steel for tightly holding superconducting lines. The band plate 1 has a radial plate structure and is placed horizontally. The band plate 1 is provided with a number of grooves 2 formed by cutting the upper and lower surfaces thereof to show a semicircular bottom and arranged in parallel with each other (only one side of the band plate is shown in FIGS. 1A and 1B).

A superconducting line 3 is contained in each of the grooves 2 of the band plate 1. The superconducting line 3 is coated with an insulating member 4 along the outer periphery thereof.

The grooves 2 of the band plate 1 are formed to show a depth greater than the diameter of the superconducting lines 3. Thus, an open space is formed at the open side of each of the grooves 2 after containing a superconducting line 3.

A stainless steel lid 5 is tightly fitted into the space of each of the grooves 2 to close the groove 2. Then, the lid 5 is welded to the band plate 1 to seal the superconducting line 3 contained in the groove 2 by means of a welding method, which will be described in greater detail hereinafter.

A laser beam 6 is emitted from a YAG laser oscillator (not shown) with an output power level of several kW. The laser beam 6 is concentrated by a condenser lens 7 to irradiate one of the oppositely disposed to-be-welded joint sections 8 between the band plate 1 and the lids 5.

A TIG (tungsten-inert-gas) torch 9 is connected to an arc welding power source (not shown) that can flow an electric current approximately up to 500 A. A TIG arc 10 is shot by the TIG weld torch 9 to the to-be-welded joint section 8 from the front side in the sense of the welding proceeding direction (indicated by an arrow 20) of the laser beam 6. The TIG arc 10 is moved in synchronism with the YAG laser oscillator to weld the to-be-welded joint section 8 between the band plate 1 and the lid 5.

TIG welding is a welding method of generating an arc between a tungsten electrode and a base metal to melt the base metal for welding in an inert shield gas atmosphere of Ar (argon), He (helium) or mixture gas thereof.

The thickness T of the to-be-welded joint section 8 between the band plate 1 and the lid 5 is typically 5 mm to 10 mm.

Generally, it is not preferable to heat a superconducting line 3 above 200 degrees Celsius in the process of manufacturing a superconducting coil in order to maintain the functional features thereof.

Now, a method of welding a superconducting coil having a configuration as described above will be described below.

The laser beam 6 emitted from the laser oscillator (not shown) is concentrated by the condenser lens 7 and is irradiated onto the to-be-welded joint section 8 between the band plate 1 and the lid 5. At the same time, a TIG arc 10 is supplied from the TIG weld torch 9 also to the to-be-welded joint section 8 from the front side in the sense of the welding proceeding direction.

A YAG laser is typically used for emitting a laser beam 6. Typically welding conditions for a YAG laser are listed below as an example.

Laser output power: 2-10 kW

Welding rate: 500-2,000 mm/min

Duty factor (pulse peek duration time/pulse cycle period): 25-100%

Frequency: 10-20,000 Hz

The condenser lens 7 may be replaced by a condenser mirror such as a paraboloidal mirror. The focal length is typically between 130 mm and 400 mm. Additionally, the YAG laser may be replaced by a fiber laser that can be adapted to large output power in the current trend of technological development, or by a conventional CO₂ laser.

A TIG arc is supplied typically under the following conditions.

Welding electric current: 180-500 A

Welding voltage: 8-15 V

Center gas flow rate for TIG arc: 3-8 liter/min

Shield gas flow rate for TIG arc: 10-30 liter/min

Angle between center line of laser beam and center line of TIG arc: 15-90 degrees

With the above-described arrangement, it is now possible to weld one of the oppositely disposed to-be-welded joint sections 8 between the band plate 1 and the lid 5 by means of a laser beam 6 and a TIG arc 10.

The other to-be-welded joint section 8 of the same lid 5 is welded by means of the laser beam 6 and the TIG arc 10.

The angle between the TIG weld torch 9 and the optical axis of the laser beam 6 is preferably within a range between 15 degrees and 90 degrees.

If a predetermined amount of excess metal is required at the to-be-welded joint section 8, a welding wire 12 may be supplied to the to-be-welded joint section 8 as filler metal. Such a welding wire 12 may be replaced by metal powder, or, alternatively, a shim member may be inserted into the gap of the joint section.

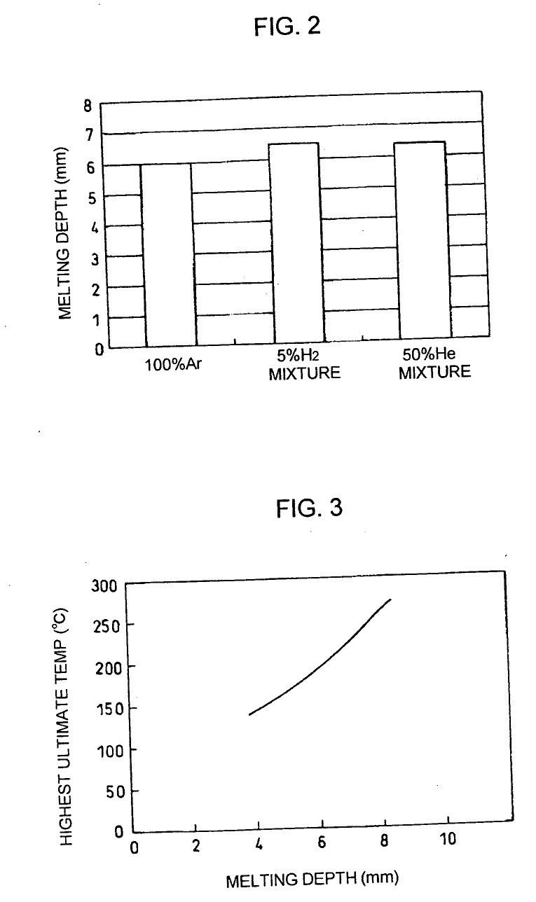

FIG. 2 is a graph illustrating a typical relationship between the shield gas and the depth of melt produced by TIG welding, when the laser output power, the welding current and the welding rate are held constant. As shown in FIG. 2, when argon gas mixed with 5% of hydrogen gas or 50% of helium gas is used, deep melting is realized compared with the case where 100% argon gas is used. That is because the electromagnetic pinching power is intensified and the TIG arc is converged.

Now, the relationship between the depth of melt and the highest ultimate temperature at the rear (inner) surface of the lid 5 by welding will be described by referring to FIG. 3. FIG. 3 illustrates the highest ultimate temperature at the rear surface of the lid 5 where the thickness T of the to-be-welded joint section 8 is 8 mm. The thickness T is shown in FIG. 1B. As the heat input of welding rises, the depth of melt increases and the highest ultimate temperature at the rear surface of the lid 5 rises. For example, it is desirable to keep the depth of melt less than 6 mm when the temperature at the rear surface needs to be lower than 200 degrees Celsius.

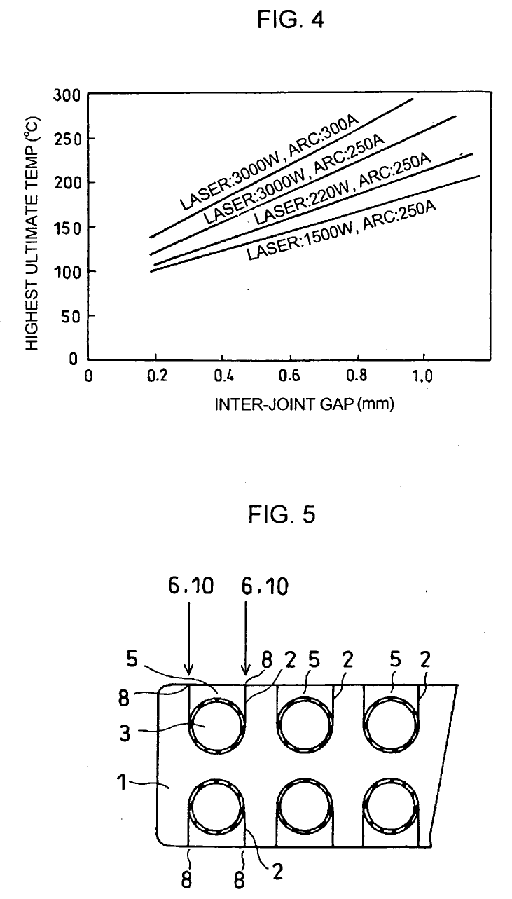

Now, the relationship between the inter-joint gap and the depth of melt will be described by referring to FIG. 4. As shown in FIG. 4, the inter-joint gap and the laser output power influence greatly the temperature rise. It is desirable to make the laser output power lower than 2.5 kW and the inter-joint gap smaller than 0.6 mm, when the temperature rise needs to be held below 200 degrees Celsius and the thickness T of the to-be-welded joint section 8 is 8 mm.

As described above, in this embodiment of the present invention, the superconducting lines, each coated with an insulating member, is contained in the respective grooves cut on the opposite surfaces of a band plate of stainless steel. Then, the openings of the grooves are closed by means of lids that are machined to be fitted into the openings to seal the superconducting lines. The heat input is controlled for welding so as to confine the depth of melt to a predetermined range by using a plurality of heat sources including a laser beam and a welding arc at the to-be-welded joint section. Thus, it is possible to precisely control the heat input of welding heat that is applied to the band plate and the lid and also applied to the superconducting lines by way of them. Then, the superconducting lines that are made of a material delicate to heat are prevented from being thermally damaged. Thus, any possible thermal deformation that can be produced by welding is advantageously suppressed to realize a method of manufacturing a superconducting coil that provides a high degree of assembling accuracy and productivity.

Additionally, it is possible to conduct arc welding prior to laser welding so as to increase the margin between the laser welding and the arc welding and to expand the arc welding region in depth direction.

Still additionally, the arc power can be raised by using a dual shield gas torch arranged around the non-wearing electrode to supply two types of shield gas. Mixture gas containing hydrogen and argon is supplied from the inner nozzle and 100% argon gas is supplied from the outer nozzle, for example. Then, even if the welding operation is conducted at high speed, it is possible to melt the band plate and the lid, which are made of stainless steel, in deeper area. Thus, the profile of the cross section of the welded joint section is improved and the arc can be stably supplied.

Preferably, the mixture gas from the inner nozzle contains hydrogen by 2 to 10% and the balance is argon. At least 2% of hydrogen is required to stabilize the arc as an effect of hydrogen. Addition of hydrogen more than 10% is not preferable because it might ignite.

The mixture gas from the inner nozzle may alternatively contain helium by 30 to 70% and the balance may be argon. The addition of helium can also stabilize the arc.

The above-described TIG welding may be alternatively replaced by plasma arc welding.

[Second Embodiment]

Now, the second embodiment of the present invention will be described by referring to FIG. 5. In the second embodiment, the parts that are same as or similar to those of the first embodiment are denoted respectively by the same reference symbols and will not be described in detail any further.

With this embodiment, the band plate 1 is arranged horizontally and provided with a number of grooves 2 formed to contain superconducting lines 3 on both sides of the band plate 1. In FIG. 5, a lid 5 is tightly fitted into the opening of each of the grooves 2 to close the groove 2.

The joint sections 8 at both sides of each of the lids 5 are welded on the upper surface of the band plate 1 simultaneously. The grooves 2 on the upper surface of the band plate 1 are located at positions opposite to and aligned with the grooves 2 on the lower surface of the band plate 1. Two to-be-welded joint sections 8 of each groove 2 are welded simultaneously as laser beams 6 and TIG arcs 10 are provided to the respective to-be-welded joint sections 8.

Thus, the oppositely disposed two lateral to-be-welded joint sections 8 of each lid 5 and the band plate 1 that is placed horizontally are welded simultaneously. Therefore, it is possible to cancel the lateral contraction of the lid 5 due to the welding heat input, and thermal deformation is prevented from taking place as a result of welding.

It is also possible to prevent thermal deformation of the entire band plate 1 by welding a plurality of lids of superconducting coils simultaneously.

[Third Embodiment]

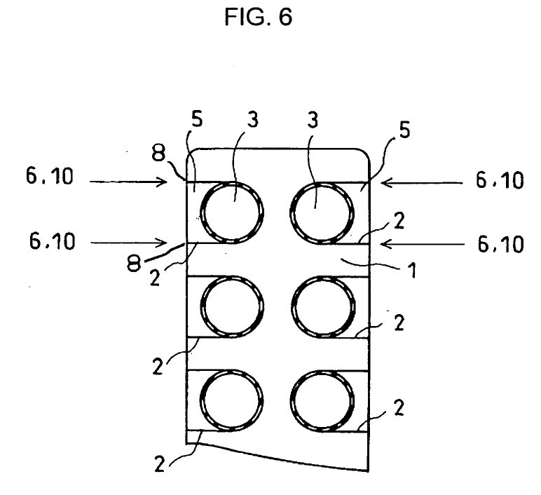

Now, the third embodiment of the present invention will be described by referring to FIG. 6.

With this embodiment, the band plate 1 is arranged vertically. The band plate 1 has a number of grooves 2 formed to contain superconducting lines 3 on the opposite surfaces of the band plate 1. In FIG. 6, the lid 5 is tightly fitted into the space of each of the grooves 2 to close the groove 2 after the superconducting line 3 is arranged in the groove 2.

A lid 5 is welded into a groove 2 on one of the oppositely disposed surfaces simultaneously with another lid 5 in another groove 2 located on the other surface at a position opposite to and aligned with the former groove 2. The four oppositely disposed to-be-welded joint sections 8 of two oppositely disposed lids 5 are welded simultaneously as laser beams 6 and TIG arcs 10 are provided to the respective to-be-welded joint sections 8.

Thus, the oppositely disposed two lateral to-be-welded joint sections 8 of each lid 5 of the band plate 1 that is placed vertically are welded simultaneously. Therefore, the vertical contraction and the lateral contraction of the lids 5 due to the welding heat input can be canceled, and thermal deformation can be prevented from taking place as a result of welding.

[Fourth Embodiment]

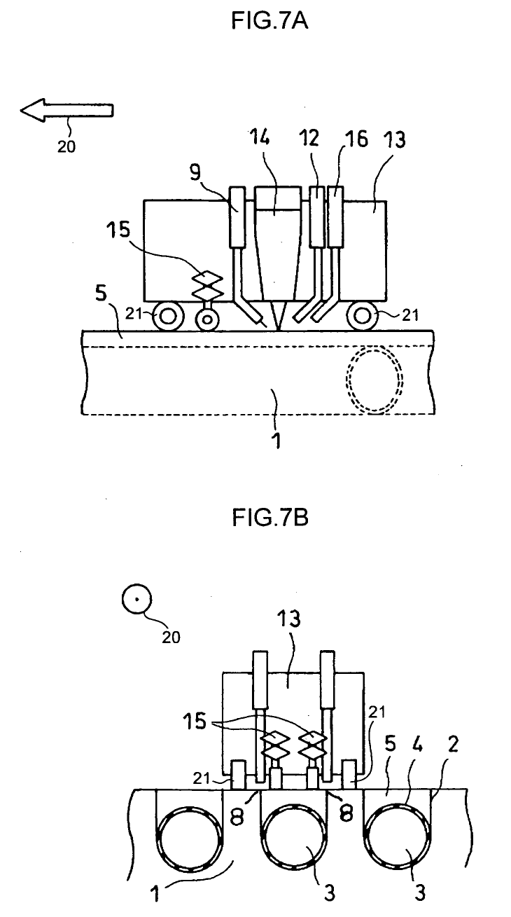

Now, the fourth embodiment of the present invention will be described by referring to FIGS. 7A and 7B. Like FIGS. 1A and 1B, FIG. 7A is a front view and FIG. 7B is a lateral cross-sectional view.

In FIGS. 7A and 7B, reference symbol 13 denotes an automotive cart that moves by itself along the to-be-welded joint sections 8 in the welding proceeding direction on the band plate 1 as indicated by an arrow 20. Wheels 21 of the automotive cart are held in direct contact with and runs on the band plate 1 in the illustrated instance. Alternatively, the cart may move on a rail or rails (not shown).

The automotive cart 13 is mounted with TIG weld torches 9, welding wires 12, welding heads 14, pressurizing rollers 15 and cooling nozzles 16. The automotive cart 13 is also mounted with power sources for generating TIG arcs and laser oscillators (not shown) adapted to oscillate and emit laser beams with several kW of power.

Alternatively, the power sources for generating TIG arcs and/or the laser oscillators may be disposed outside of the cart 13. In such a case, the laser beams and the signals may be transmitted to the welding heads 14 by way of quartz fibers, for example.

As laser welding units and arc welding units are mounted on an automotive cart 13 that runs on a band plate 1 along the to-be-welded joint sections 8 in the welding proceeding direction as described above, the welding operation is automated and is improved in productivity.

The pressurizing rollers 15 are mounted on the automotive cart 13 in such a way that they rotate and move on a lid 5 as the automotive cart 13 moves along the to-be-welded joint sections 8. These pressurizing rollers 15 apply load on the lid 5 to suppress thermal deformation that may take place as a result of welding of the lid 5 when they are heated for welding.

The cooling nozzles 16 mounted on the automotive cart 13 cool the welding beads and their peripheries from the rear side in the sense of the welding proceeding direction.

Cooling gas such as carbon dioxide or nitrogen gas can be blown from the cooling nozzles 16. Alternatively, solid such as dry ice or liquid such as mist of moisture may be applied for cooling the welding beads and their peripheries.

As the functional feature of cooling a welding bead and its periphery as the automotive cart 13 moves is provided, thermal deformation of the band plate 1 and the lid 5 due to welding can be suppressed or avoided when they are heated for welding.

[Other Embodiments]

The embodiments in accordance with the present invention explained above are merely samples, and the present invention is not restricted thereto. It is, therefore, to be understood that, within the scope of the appended claims, the present invention can be practiced in a manner other than as specifically described herein.

What is claimed is:

1. A method of manufacturing a superconducting coil, the method comprising:
containing a superconducting line coated with an insulating member in a groove formed on a surface of a stainless steel plate;
fitting a stainless steel lid in outer side of the superconducting line in an opening in the groove, the lid being formed to fit in the groove; and
welding the plate and the lid to seal at joint sections, wherein
the welding is conducted using a plurality of heat sources including a laser and an arc so that melting depth at the joint section is within a predetermined range.

2. The method according to claim 1, wherein the lid has two joint sections, and the welding of the joint sections of the lid is conducted simultaneously.

3. The method according to claim 1, wherein:
the plate has a plurality of grooves, the superconducting line each is contained in one of the grooves; and
the welding of the joint sections of each one of the plurality of lids is conducted simultaneously.

4. The method according to claim 1, wherein:
the plate has two mutually opposite surfaces, each of the surfaces has a plurality of grooves at positions corresponding to the grooves on opposite surface, the superconducting line each is contained in one of the grooves, and
the welding of the joint sections at positions corresponding to the positions on the opposite surface is conducted simultaneously.

5. The method according to claim 4, wherein the plate is arranged upright while the welding is conducted.

6. The method according to claim 1, wherein the welding using an arc includes TIG welding or plasma welding.

7. The method according to claim 1, wherein the welding is conducted using mixture gas of hydrogen and argon as arc shielding gas.

8. The method according to claim 7, wherein the mixture gas contains 2 to 10% of hydrogen and the balance of argon.

9. The method according to claim 1, wherein the welding is conducted using mixture gas of helium and argon as arc shielding gas.

10. The method according to claim 1, further comprising
mounting a laser welding mechanism and an arc welding mechanism on an automotive cart, wherein
the welding step includes moving the cart along the welding section.

11. The method according to claim 10, further comprising
mounting a pressurizing roller on the automotive cart, wherein
the lid is pressed with the pressurizing roller while the cart is moved.

12. The method according to claim 10, further comprising
mounting a cooling mechanism on the automotive cart, wherein welding bead and its vicinity are cooled in rear region of the joint section after the welding is conducted.

13. The method according to claim 1, wherein the plate is a band plate.

14. A superconducting coil comprising:
a stainless steel plate having at least one surface with at least one groove;
a superconducting coil coated with an insulator contained in the groove; and
a stainless steel lid fitted into the groove at outer side of the superconducting line; wherein:
the lid has two joint sections on its sides where the lid is welded with the plate; and
the joint sections have been welded using a plurality of heat sources including a laser and an arc so that melting depth at the joint section is within a predetermined range.

15. A welding device for manufacturing a superconducting coil, the device adapted to be used for welding a stainless steel plate and a stainless steel lid to seal joint sections between the plate and the lid, the plate having at least one surface with at least one groove containing a superconducting coil coated with an insulator, the lid being fitted into the groove at outer side of the superconducting line, the device comprising:
an automotive cart adapted to move along the joint sections;
a laser welding mechanism for welding the joint sections, the laser welding mechanism mounted on the cart; and
an arc welding mechanism for welding the joint sections, the arc welding mechanism mounted on the cart.

16. The welding device according to claim 15 further comprising a pressurizing mechanism for pressurizing the lid, the pressurizing mechanism mounted on the cart.

17. The welding device according to claim 15 further comprising a cooling mechanism for cooling the joint sections, the cooling mechanism mounted on the cart.
